(19) United States
(12) Patent Application Publication
(10) Pub. No.: US 2026/0144122 A1
(43) Pub. Date: May 21, 2026

(54) SEMICONDUCTOR DEVICE AND METHOD

(71) Applicant: Taiwan Semiconductor Manufacturing Co., Ltd., Hsinchu (TW)

(72) Inventors: Wei-Hsiang Tu, Hsinchu (TW); Kuan-Cheng Peng, Kaohsiung City (TW); Kuo-Chin Chang, Chiayi City (TW); Kathy Wei Yan, Hsinchu (TW); Mirng-Ji Lii, Sinpu Township (TW)

(21) Appl. No.: 18/954,798

(22) Filed: Nov. 21, 2024

(51) Int. Cl. H01L 23/00

(52) U.S. Cl. CPC H10W 72/90; H10W 72/019; H10W 72/20; H10W 72/01951; H10W 72/244; H10W 72/29; H10W 72/923; H10W 72/934; H10W 72/9415; H10W 72/942

(57) ABSTRACT

A method includes forming a passivation structure over a first conductive feature; forming an opening in the passivation structure to expose the first conductive feature; forming a protection layer over the passivation structure and within the opening, wherein the protection layer over the passivation structure has a first thickness; recessing a portion of the protection layer to form a recess, wherein the recess exposes the first conductive feature, wherein a second thickness of the protection layer at a sidewall of the recess is smaller than the first thickness; and forming a second conductive feature over the protection layer and within the recess.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 16 are cross-sectional views of intermediate stages in the formation of an under bump metallization (UBM) structure of a semiconductor device, in accordance with some embodiments.

FIGS. 17A through 17F are cross-sectional views of recessed surfaces of a protection layer, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide methods and structures for forming a protection layer underneath an under bump metallization (UBM). The surface of the protection layer covered by the UBM may be formed having a sloped and/or stepped surface profile, which can reduce interface stresses at the protection layer, such as between the protection layer and the UBM. This can reduce the risk of cracking, delamination, or other stress-related defects.

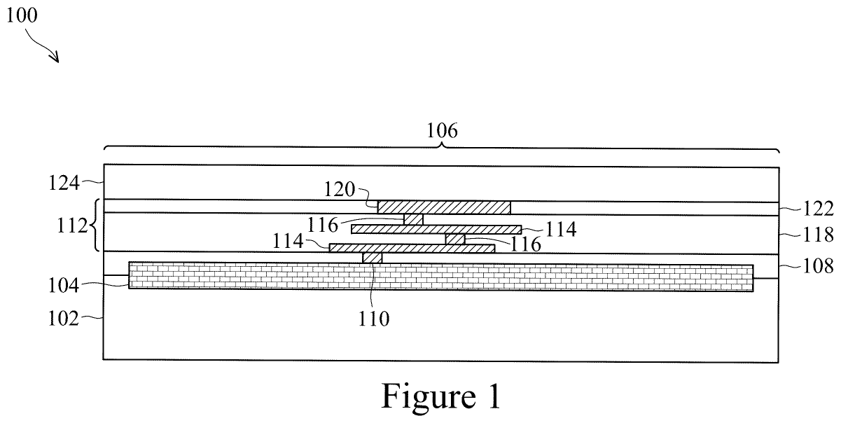

FIGS. 1 through 16 illustrate cross-sectional views of intermediate stages in the formation of an under bump metallization (UBM) structure of a semiconductor device, in accordance with some embodiments of the present disclosure. It is appreciated that although a device wafer and a device die are used as examples, the embodiments of the present disclosure may also be applied to form conductive features in other devices (e.g., package components) including, and not limited to, package substrates, interposers, packages, and the like. For example, the embodiments described herein may be applied to a semiconductor package, in some cases.

FIG. 1 illustrates a cross-sectional view of a semiconductor device 100. In some embodiments, the semiconductor device 100 is a device wafer including active devices and/or passive devices, which are represented as integrated circuit devices 104. The semiconductor device 100 may be singulated to form a plurality of chips/dies 106 therefrom. In FIG. 1, a single die 106 is illustrated. In some embodiments, the semiconductor device 100 is an interposer wafer, which is free from active devices and may include passive devices. In some embodiments, the semiconductor device 100 is a package substrate strip, which includes a core-less package substrate or a cored package substrate with a core therein. In subsequent discussion, a device wafer is used as an example of the semiconductor device 100, and the semiconductor device 100 may be referred to as a wafer. The embodiments of the present disclosure may also be applied to interposer wafers, package substrates, packages, or the like.

In some embodiments, the dies 106 comprise logic dies (e.g., central processing units (CPUs), graphics processing units (GPUs), system-on-chips (SoCs), application processors (APs), microcontrollers, application-specific integrated circuit (ASIC) dies, or the like), memory dies (e.g., dynamic random access memory (DRAM) dies, static random access memory (SRAM) dies, high bandwidth memory (HBM) dies, or the like), power management dies (e.g., power management integrated circuit (PMIC) dies), radio frequency (RF) dies, sensor dies, micro-electro-mechanical-system (MEMS) dies, signal processing dies (e.g., digital signal processing (DSP) dies or the like), front-end dies (e.g., analog front-end (AFE) dies), the like, or a combination thereof. Other types of dies, chips, integrated circuit devices, semiconductor devices, or the like are possible.

In some embodiments, the semiconductor device 100 includes a semiconductor substrate 102 and features formed at a top surface of the semiconductor substrate 102. The semiconductor substrate 102 may be a bulk semiconductor, a semiconductor-on-insulator (SOI) substrate, or the like, which may be doped (e.g., with a p-type or an n-type dopant) or undoped. The semiconductor substrate 102 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or a glass substrate. Other substrates, such as a multi-layered or gradient substrate may also be used. In some embodiments, the semiconductor material of the semiconductor substrate 102 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Shallow trench isolation (STI) regions (not separately illustrated) may be formed in the semiconductor substrate 102 to isolate active regions in the semiconductor substrate 102. Vias (not separately illustrated) may be formed extending into the semiconductor substrate 102 or through the semiconductor substrate 102 (e.g., through-vias) and may be used to electrically inter-couple features on opposite sides of the semiconductor device 100.

In some embodiments, the semiconductor device 100 is a stacked device that includes multiple semiconductor substrates 102. For example, the semiconductor device 100 may be a memory device such as a hybrid memory cube (HMC) module, a high bandwidth memory (HBM) module, or the like that includes multiple memory dies. In such embodiments, the semiconductor device 100 includes multiple semiconductor substrates 102 interconnected by through-substrate vias (TSVs). Each of the semiconductor substrates 102 may (or may not) have an interconnect structure (e.g., interconnect structure 112, described below).

In some embodiments, the semiconductor device 100 includes integrated circuit devices 104, which are formed on the top surface of semiconductor substrate 102. The integrated circuit devices 104 may include complementary metal-oxide semiconductor (CMOS) transistors, fin field-effect transistors (FinFETs), nanostructure FETs, resistors, capacitors, diodes, and the like. The details of the integrated circuit devices 104 are not illustrated herein. In some embodiments, the semiconductor device 100 is used for forming interposers (which are free from active devices), and the semiconductor substrate 102 may be a semiconductor substrate or a dielectric substrate.

In some embodiments, an inter-layer dielectric (ILD) 108 may be formed over the semiconductor substrate 102 and may fill spaces between gate stacks of transistors (not separately illustrated) in the integrated circuit devices 104. In some embodiments, the ILD 108 is formed of phosphosilicate glass (PSG), borosilicate glass (BSG), boron-doped phosphosilicate glass (BPSG), fluorine-doped silicate glass (FSG), silicon oxide, silicon nitride, silicon oxynitride, low-k dielectric materials, combinations or multiple layers thereof, or the like. The ILD 108 may be formed using a suitable technique such as spin coating, flowable chemical vapor deposition (FCVD), or the like. In some embodiments, the ILD 108 is formed using a deposition method such as plasma-enhanced chemical vapor deposition (PECVD), low-pressure chemical vapor deposition (LPCVD), or the like.

Contact plugs 110 are formed in the ILD 108, and are used to electrically connect the integrated circuit devices 104 to overlying metal lines and/or vias. In some embodiments, the contact plugs 110 are formed of one or more conductive materials, such as tungsten, aluminum, copper, titanium, tantalum, titanium nitride, tantalum nitride, alloys thereof, multi-layers thereof, or the like. The formation of the contact plugs 110 may include forming contact openings in the ILD 108, depositing the conductive material(s) into the contact openings, and performing a planarization process (e.g., a chemical mechanical polish (CMP) process, a mechanical grinding process, an etch-back process, or the like) to level top surfaces of the contact plugs 110 with top surfaces of the ILD 108.

An interconnect structure 112 is formed over the ILD 108 and the contact plugs 110, in accordance with some embodiments. The interconnect structure 112 includes metal lines 114 and metal vias 116 formed in a plurality of dielectric layers 118. In some cases, the dielectric layers 118 may be referred to as inter-metal dielectrics (IMDs). The metal lines 114 that are formed at a same level (e.g., at, on, or in the same dielectric layer 118) may collectively be referred to as a metal layer, a redistribution layer, a metallization pattern, or the like. In some embodiments, the interconnect structure 112 includes a plurality of metal layers including metal lines 114 that are interconnected through metal vias 116. The metal lines 114 and the metal vias 116 may be formed of copper, copper alloys, other metals, or the like.

In some embodiments, the dielectric layers 118 are formed of low-k dielectric materials. For example, the dielectric constants (k-values) of the low-k dielectric materials may be lower than about 3.0. The dielectric layers 118 may comprise carbon-containing low-k dielectric materials, hydrogen silsesquioxane (HSQ), methylsilsesquioxane (MSQ), combinations or multiple layers thereof, or the like. In some embodiments, the dielectric layers 118 may comprise PSG, BSG, BPSG, undoped silicate glass (USG), or the like. In some embodiments, the dielectric layers 118 may comprise oxides (e.g., silicon oxide or the like), nitrides (e.g., silicon nitride or the like), combinations thereof, or the like. In some embodiments, the dielectric layers 118 may comprise a polymer material such as polyimide, polybenzoxazole (PBO), benzocyclobutene (BCB), or the like. The dielectric layers 118 may be formed by a suitable technique such as CVD, FCVD, PECVD, LPCVD, spin coating, or the like.

The formation of the metal lines 114 and the metal vias 116 in the dielectric layers 118 may include single damascene processes and/or dual damascene processes. In a single damascene process, a trench or a via opening is formed in one of the dielectric layers 118 and the trench or the via opening is filled with a conductive material. A planarization process, such as a CMP process, is then performed to remove excess portions of the conductive material, which may be higher than top surfaces of the dielectric layer 118, leaving a metal line 114 or a metal via 116 in the corresponding trench or via opening. In a dual damascene process, a trench and a via opening are both formed in a dielectric layer 118, with the via opening underlying and being connected to the trench. Conductive materials are filled into the trench and the via opening to form a metal line 114 and a metal via 116, respectively. The conductive materials may include a diffusion barrier layer and a copper-containing metallic material over the diffusion barrier layer. The diffusion barrier layer may include titanium, titanium nitride, tantalum, tantalum nitride, or the like. The metal lines 114 and metal vias 116 may be formed using other techniques in other embodiments.

Top metal features 120 may be formed in a top dielectric layer 122, such as metal lines, metal vias, metal pads, or the like. The top metal features 120 may be formed of the same or similar materials and using the same or similar processes as the metal lines 114 and/or the metal vias 116. The top dielectric layer 122 may be formed of the same or similar materials and using the same or similar processes as the dielectric layers 118. The top metal features 120 may refer to a topmost metal layer in the interconnect structure 112. Although FIG. 1 illustrates the interconnect structure 112 as having a particular number of metal layers, any number of metal layers may be included in other embodiments. The top dielectric layer 122 and the underlying dielectric layer 118 that is immediately underlying the top dielectric layer 122 may be formed as a single continuous dielectric layer, may be formed as different dielectric layers using different processes, and/or may be formed of different materials.

A first passivation layer 124 may be formed over the interconnect structure 112 (e.g., over the top dielectric layer 122). The first passivation layer 124 may be formed of a single material layer or may comprise two or more layers of different materials, which may be collectively referred to as a first passivation structure. In some embodiments, the first passivation layer 124 may include PSG, BSG, BPSG, USG, or the like. In some embodiments, the first passivation layer 124 may include an inorganic dielectric material, such as silicon oxide, silicon nitride, silicon oxynitride, silicon carbide, silicon oxycarbide, low-k dielectric materials, combinations thereof, multi-layers thereof, or the like. For example, in some embodiments, the first passivation layer 124 may be a passivation structure comprising a layer of USG over a layer of silicon nitride. Other materials or combinations thereof are possible. The first passivation layer 124 may be deposited using one or more suitable techniques, such as CVD, physical vapor deposition (PVD), atomic layer deposition (ALD), or the like. In some embodiments, top surfaces of the top dielectric layer 122 and the top metal features 120 are coplanar (e.g., level with one another). Accordingly, the layer(s) of the first passivation layer 124 may be planar layers. In some embodiments, the top metal features 120 protrude higher than top surfaces of the top dielectric layer 122, and in such embodiments, the first passivation layer 124 may not be planar.

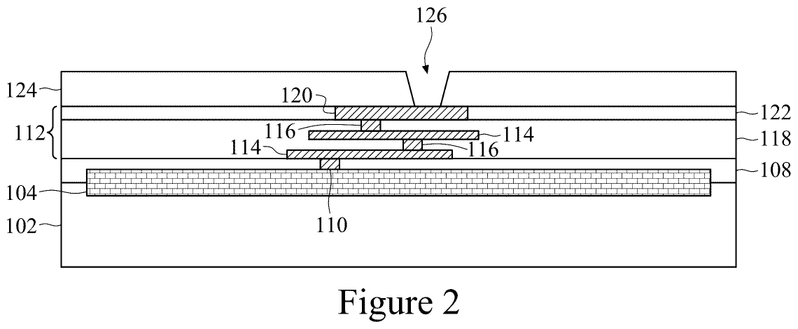

In FIG. 2, openings 126 are formed in the first passivation layer 124, in accordance with some embodiments. The openings 126 may be formed using a suitable etching process, such as a dry etching process. The etching process may include, for example, forming a patterned etching mask (not separately illustrated) over the interconnect structure 112, such as a patterned photoresist, and then etching the first passivation layer 124 using the patterned etching mask. The patterned etching mask is then removed using a suitable process. The openings 126 may extend fully through the first passivation layer 124 and may expose top metal features 120.

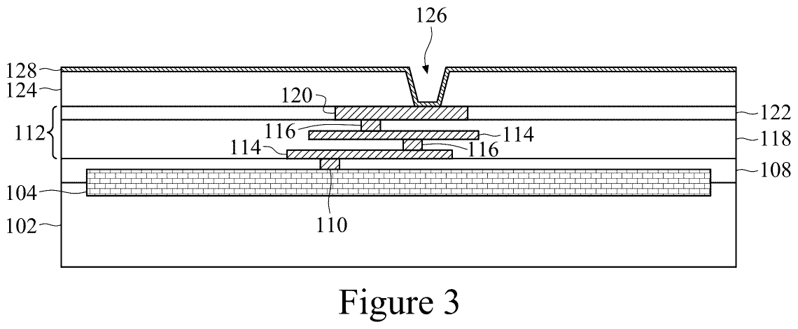

In FIG. 3, a seed layer 128 is formed over the first passivation layer 124, in the openings 126, and over the exposed top metal features 120, in accordance with some embodiments. The seed layer 128 may comprise one or more metal layers. For example, in some embodiments, the seed layer 128 may comprise a titanium layer and a copper layer over the titanium layer. In some embodiments, the seed layer 128 comprises a copper layer in contact with the first passivation layer 124 and the top metal features 120. Other materials or combinations of materials are possible. The seed layer 128 may be formed by a suitable deposition process such as CVD, PVD, metal organic chemical vapor deposition (MOCVD), or the like.

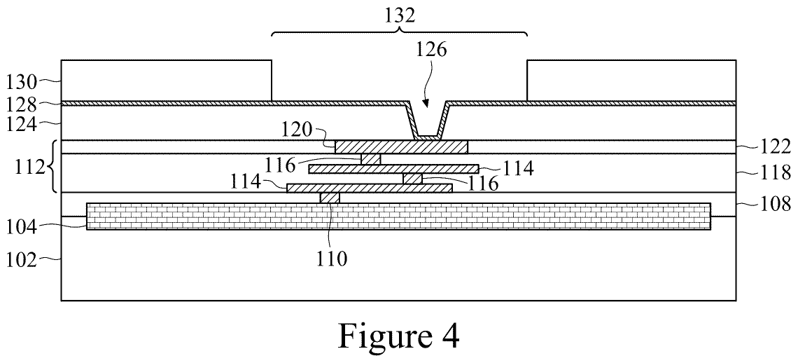

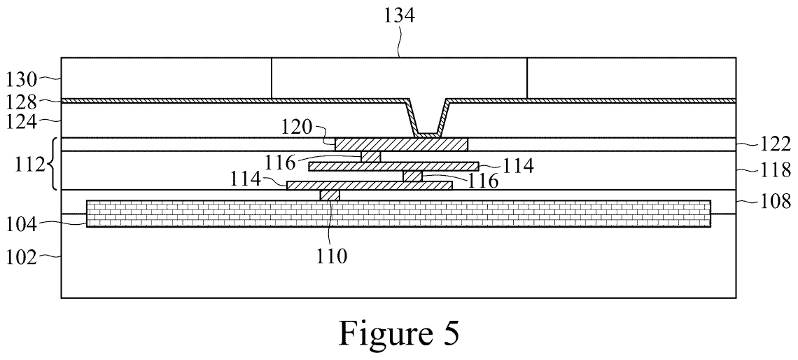

In FIG. 4, a patterned photoresist 130 is formed over the seed layer 128, in accordance with some embodiments. The patterned photoresist 130 may be formed, for example, by depositing a photosensitive layer over the seed layer 128 using spin coating or the like. The photosensitive layer may be a single material layer or may comprise multiple layers of different materials. The photosensitive layer may then be patterned by exposing the photosensitive layer to a patterned energy source (e.g., a patterned light source) and developing the photosensitive layer to remove exposed or unexposed portions of the photosensitive layer, thereby forming the patterned photoresist 130. Openings 132 are formed in the patterned photoresist 130 that expose the seed layer 128. As shown in FIG. 4, an opening 132 may overlap one or more openings 126. The pattern of the patterned photoresist 130 corresponds to redistribution layers (RDLs) subsequently formed in the patterned photoresist 130, as will be discussed below with respect to FIG. 5.

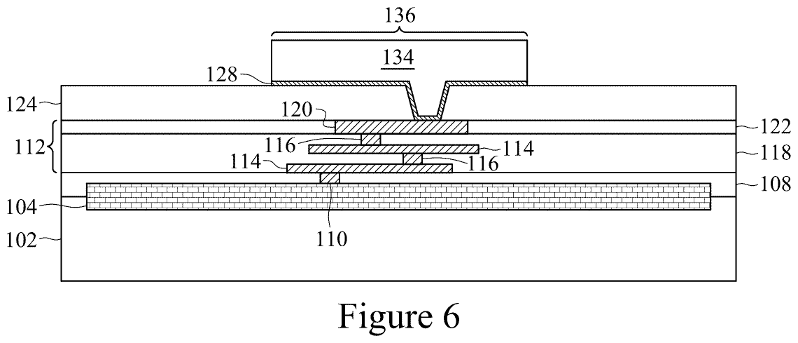

In FIG. 5, a conductive material 134 is formed over exposed portions of the seed layer 128, in accordance with some embodiments. The conductive material 134 may fill the openings 126 and at least partially fill the openings 132. The conductive material 134 may be formed by plating, such as electroplating, electroless plating, or the like. The conductive material 134 may comprise a metal, such as copper, titanium, tungsten, aluminum, aluminum copper, nickel, cobalt, ruthenium, a combination thereof, an alloy thereof, or the like. The combination of the conductive material 134 and underlying portions of the seed layer 128 form redistribution layers (e.g., RDLs 136 of FIG. 6).

In FIG. 6, the patterned photoresist 130 and portions of the seed layer 128 on which the conductive material 134 is not formed are removed. The patterned photoresist 130 may be removed by an acceptable ashing or stripping process, such as using an oxygen plasma or the like. Once the patterned photoresist 130 is removed, exposed portions of the seed layer 128 are removed using an acceptable etching process, such as wet or dry etching. One or more optional cleaning processes may also be performed. The conductive material 134 and remaining underlying portions of the seed layer 128 form RDLs 136, in accordance with some embodiments. Each of the RDLs 136 may include a via portion extending through the first passivation layer 124 and a trace/line portion over the first passivation layer 124. The via portions of the RDLs 136 physically and electrically connect to top metal features 120 of the interconnect structure 112. Although only one RDL 136 is illustrated in FIG. 6, any number of the RDLs 136 may be formed over each of the dies 106.

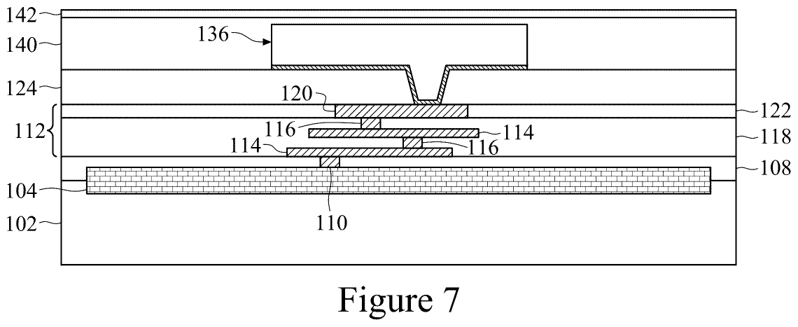

In FIG. 7, a second passivation layer 140 and a third passivation layer 142 are formed over the first passivation layer 124 and over and along sidewalls and top surfaces of the RDL 136. The second passivation layer 140 and the third passivation layer 142 may be collectively referred to as a second passivation structure. The second passivation layer 140 and the third passivation layer 142 may be formed of materials the same as or different from the materials of the first passivation layer 124. For example, in some embodiments, the second passivation layer 140 and the third passivation layer 142 may be formed of inorganic dielectric materials, such as silicon oxide, silicon nitride, silicon oxynitride, silicon carbide, silicon oxycarbide, combinations thereof, multi-layers thereof, or the like. The second passivation layer 140 may be made of materials that have a high etching selectivity from the material of the third passivation layer 142, such that the second passivation layer 140 may act as an etch stop layer for a process used to etch the third passivation layer 142. For example, in some embodiments, the second passivation layer 140 may comprise silicon oxide and the third passivation layer 142 may comprise silicon nitride. Other materials or combinations of materials are possible. In other embodiments, the second passivation layer 140 may be a single layer, and the third passivation layer 142 may be omitted. The second passivation layer 140 and the third passivation layer 142 may be deposited using a suitable technique such as CVD, ALD, PECVD, FCVD, spin coating, or the like. In some embodiments, a planarization process (e.g., a CMP process, a grinding process, or the like) is performed on the second passivation layer 140 before deposition of the third passivation layer 142. In such embodiments, the planarization process levels the top surface of the second passivation layer 140. As shown in FIG. 7, the RDL 136 may remain covered by the second passivation layer 140 after the planarization process.

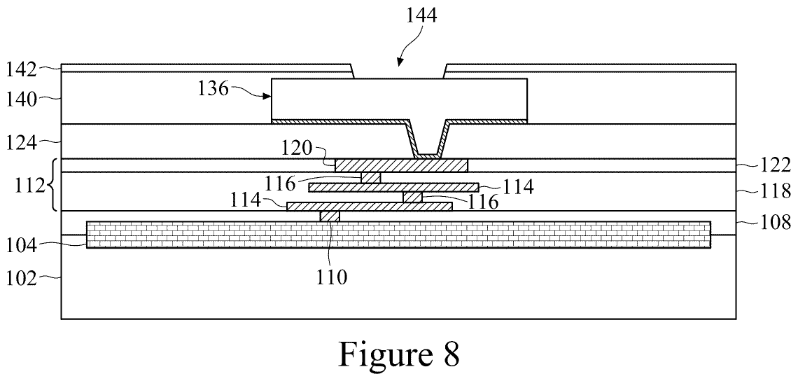

In FIG. 8, openings 144 are formed extending through the second passivation layer 140 and the third passivation layer 142, in accordance with some embodiments. The openings 144 may be formed using one or more suitable etching processes, such as one or more wet or dry etching processes. In some embodiments, a patterned etching mask (not separately illustrated) is formed over the third passivation layer 142, such as a patterned photoresist. The second passivation layer 140 and the third passivation layer 142 are then etched using the patterned etching mask. In some embodiments, the third passivation layer 142 is etched using a first etching step and the second passivation layer 140 is etched using a second etching step, which may be different from the first etching step. The patterned etching mask is then removed using a suitable process. The openings 144 may extend fully through the second passivation layer 140 and the third passivation layer 142 and may expose RDLs 136. The sidewalls of the openings 144 may be sloped (e.g., oblique, tilted, tapering, or the like) or may be substantially vertical.

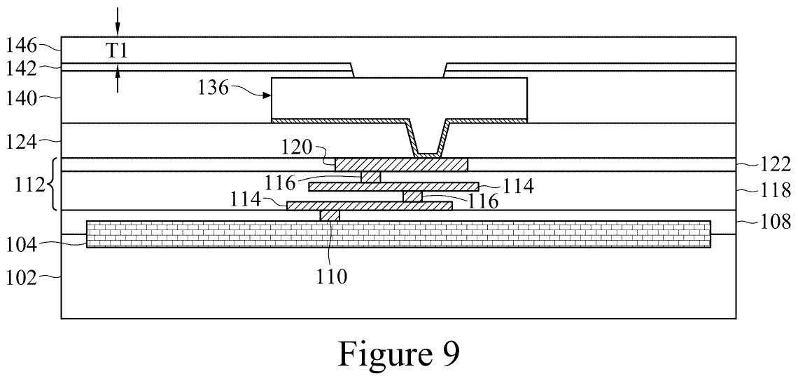

In FIG. 9, a protection layer 146 is formed over the third passivation layer 142 and within the opening 144, in accordance with some embodiments. In some embodiments, the protection layer 146 is formed of a polymer material (which may be photosensitive) such as polyimide, polybenzoxazole (PBO), benzocyclobutene (BCB), an epoxy, or the like. The protection layer 146 may be formed by CVD, PECVD, a spin coating process, or the like. In some embodiments, the formation of the protection layer 146 includes coating the protection layer 146 in a flowable form, and then performing a baking or curing process to harden the protection layer 146. A planarization process, such as a CMP process or a grinding process, may be performed to level the top surface of the protection layer 146. In some embodiments, the protection layer 146 has a thickness T1 over the third passivation layer 142 that is in the range of about 2 μm to about 5 μm, though other thicknesses are possible.

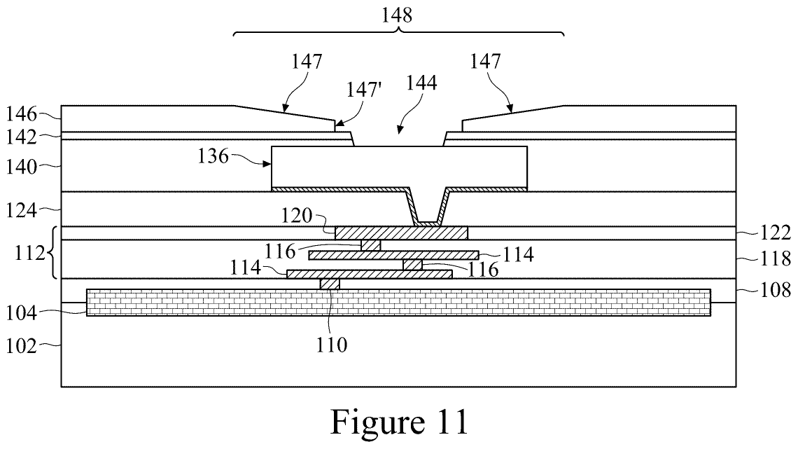

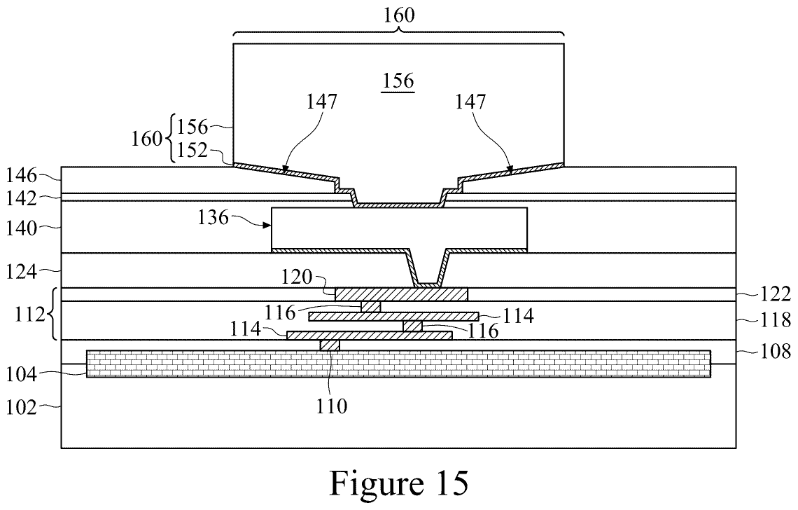

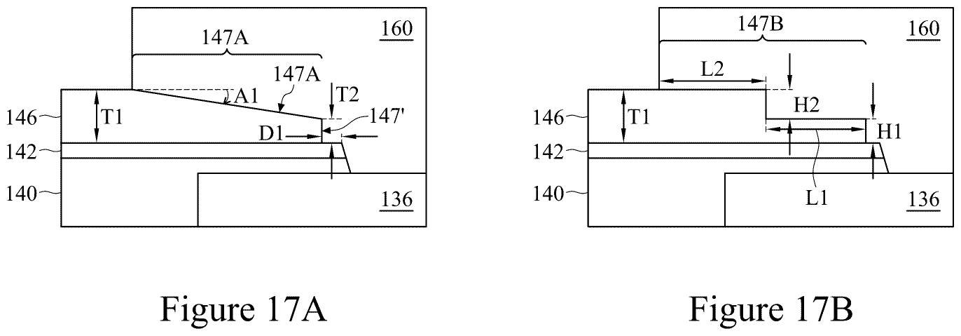

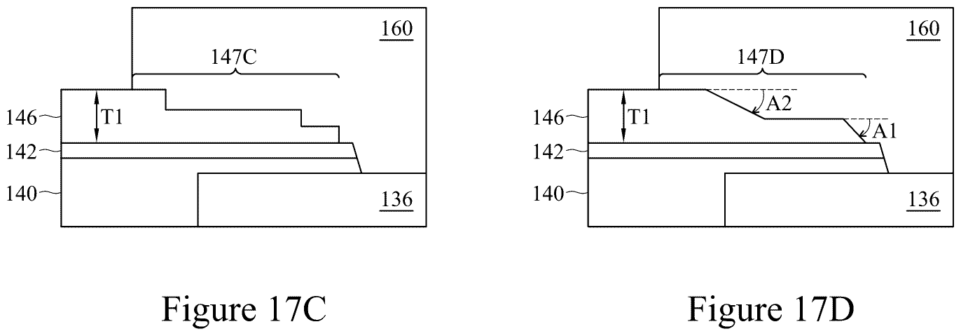

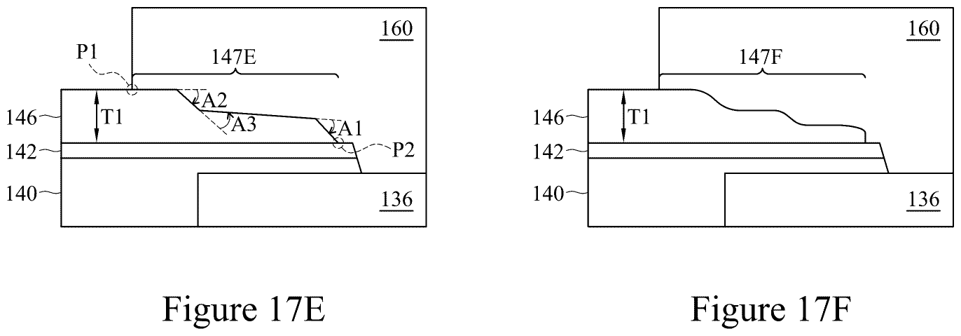

The protection layer 146 may then be patterned to form recesses 148 (see FIG. 11), in accordance with some embodiments. The recesses 148 are formed in the protection layer 146 to expose the RDLs 136 for physical and electrical connection of subsequently-formed under bump metallizations (UBMs) 160 (see FIG. 15). Accordingly, a recess 148 may overlap one or more openings 144. For embodiments in which the protection layer 146 comprises a photosensitive material, the protection layer 146 may be patterned using suitable photolithographic techniques. For example, a photosensitive protection layer 146 may be patterned by exposing the protection layer 146 to a patterned energy source (e.g., a patterned light source) and developing the protection layer 146 to remove exposed or unexposed portions of the protection layer 146. In some embodiments, during formation of the recesses 148, the protection layer 146 may be patterned such that surfaces of the protection layer 146 that are subsequently covered by the UBMs 160 are reshaped to have a particular profile, such as a sloped profile, a stepped profile, a tapered profile, a curved profile, or a combination thereof. A thickness of the protection layer 146 within a recess 148 is smaller than a thickness (e.g., thickness T1) of the protection layer 146 outside of the recess 148. In some embodiments, a thickness of the protection layer 146 within a recess 148 generally tapers toward the center of the recess 148, though the profile of recessed surfaces 147 of the protection layer 146 within the recess 148 may be sloped, stepped, and/or curved. In some cases, reshaping the protection layer 146 underneath the UBMs 160 as described herein may reduce interface stress between the UBMs 160 and the protection layer 146, or may reduce interface stress between the second passivation structure (e.g., the second passivation layer 140 and/or the third passivation layer 142) and the protection layer 146. In some cases, forming recessed surfaces 147 underneath the UBMs 160 may reduce interface stress by about 15% or more. FIGS. 17A-17F, described below, illustrate non-limiting examples of some surface profiles of the protection layer 146 that may be formed, in accordance with some embodiments.

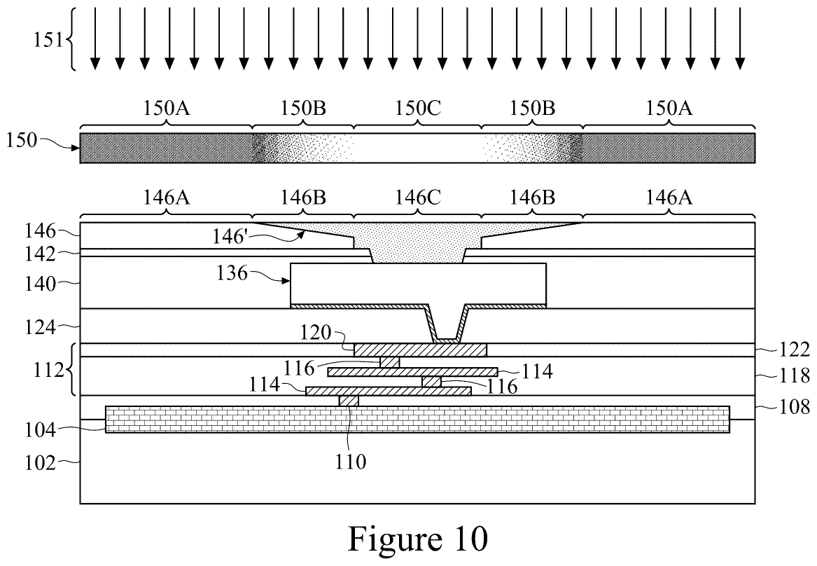

FIGS. 10-11 illustrate intermediate steps in the formation of a recess 148 and the reshaping of the protection layer 146 to have sloped surface profiles (e.g., at recessed surfaces 147), in accordance with some embodiments. The process and surface profiles described for FIGS. 10-11 are intended as an illustrative example, and other processes or surface profiles are possible. FIGS. 10-11 illustrates the performing of a “grayscale” photolithography process, in accordance with some embodiments. In FIG. 10, an exposed region 146′ is formed in the protection layer 146 by exposing the protection layer 146 to the energy of a light source 151 using a grayscale photolithography mask 150. The grayscale photolithography mask 150 is a photolithography mask having opacity variations that allow for control of the spatial distribution of the exposure received by protection layer 146. In other words, the amount of exposure received at different locations of the protective layer 146 may be controlled. The portions of the exposed region 146′ that received greater exposure have a greater depth than portions of the exposed region 146′ that received less exposure. In this manner, the depth profile or shape of the exposed region 146′ may be controlled through the utilization of a corresponding grayscale photolithography mask 150.

With reference to the example of FIG. 10, the illustrated grayscale photolithography mask 150 comprises multiple opacity regions 150A-C. The different opacity regions 150A-C allow for corresponding underlying regions 146A-C of the protective layer 146 to receive different amounts of exposure from the light source 151. The opacity region 150A of the grayscale photolithography mask 150 is fully opaque, and thus the corresponding underlying region 146A of the protective layer 146 is not exposed to the light source 151. The opacity region 150C of the grayscale photolithography mask 150 is substantially transparent, such that the underlying region 146C of the protective layer 146 is fully exposed to the light source 151, and the depth of the corresponding portion of the exposed region 146′ extends fully through the protective layer 146. The opacity region 150B of the grayscale photolithography mask 150 has a varying opacity (e.g., has different opacities), such that the underlying region 146B of the protective layer 146 receives a correspondingly varying exposure, and the corresponding portion of the exposed region 146′ has a correspondingly varying depth. For example, the opacity region 150B is shown having an opacity gradient from mostly opaque near opacity region 150A to mostly transparent near opacity region 150C, which results in the exposed region 146′ having a depth gradient from a smaller depth near region 146A to a larger depth near region 146C.

The grayscale photolithography mask 150 shown in FIG. 10 is an example, and other configurations of varying opacity of a grayscale photolithography mask 150 are possible, which may allow for other depth profiles of an exposed region 146′ than shown. In other embodiments, multiple exposures using multiple photolithography masks may be used to control the depth profile of an exposed region 146′. For example, a relatively transparent photolithography mask may be used in an exposure step to form relatively deep portions of an exposed region 146′, and a relatively opaque photolithography mask may be used in a separate exposure step to form relatively shallow portions of the same exposed region 146′. In some embodiments, the use of multiple exposures may be used to form an exposed region 146′ having a stepped depth profile. These and other variations and combinations thereof are considered within the scope of the present disclosure.

In FIG. 11, the protection layer 146 is developed to form the recess 148, in accordance with some embodiments. The protection layer 146 may be developed using a suitable photolithographic development technique, such as a wet chemical process or another suitable process. In some embodiments, the developing removes the exposed region 146′ of the protective layer 146 to form the recess 148. In this manner, controlling the exposure of the protective layer 146 to control the depth profile of the exposed region 146′ can control the shape and size of the recess 148. For example, in FIG. 11, the sloped depth profile of the exposed region 146′ forms corresponding sloped recessed surfaces 147 of the protection layer 146 within the recess 148. For example, a sloped recessed surface 147 extends from an edge of the recess 148 to a sidewall 147′ of the protection layer 146 within the recess 148. The recessed surfaces 147 may surround the opening 144. The sidewalls 147′ of the protection layer 146 within the recess 148 are shown as substantially vertical, but may be sloped in other embodiments. In some embodiments, a top surface of the second passivation structure (e.g., a top surface of the third passivation layer 142) is exposed by the recess 148, but in other embodiments, the second passivation structure remains covered by the protection layer 146. In other words, sidewalls 147′ of the protection layer 146 and the second passivation structure may be laterally offset or may be laterally aligned. As shown in FIG. 11, the opening 144 within the recess 148 exposes the underlying RDL 136. In some embodiments, a width of the recess 148 may be greater than a width of the underlying RDL 136. In other words, the recessed surfaces 147 may laterally protrude beyond the RDL 136. In some embodiments, the recessed surfaces 147 may laterally surround the RDL 136.

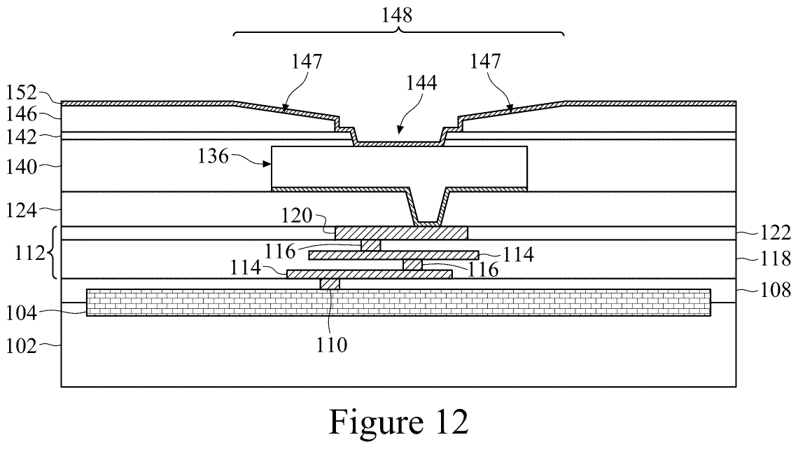

FIGS. 12-15 illustrate intermediate steps in the formation of a UBM 160 (see FIG. 15), in accordance with some embodiments. The UBM 160 is a conductive feature formed in the recess 148 that makes physical and electrical contact to the RDL 136 and allows for external connection to the structure. Portions of the UBM 160 extend along recessed surfaces 147 of the protection layer 146. By forming recessed surfaces 147 underneath the UBM 160 as described herein, interface stress between the UBM 160 and the protection layer 146 may be reduced, which can reduce the risk of delamination or cracking and can improve resistance, device performance, or yield. The process described for FIGS. 12-15 below is an example, and UBMs may be formed in recesses 148 using other materials or techniques in other embodiments.

In FIG. 12, a seed layer 152 is formed over the protection layer 146, over the RDL 136, over the second passivation layer 140, over the third passivation layer 142, within the recess 148, and within the opening 144, in accordance with some embodiments. In some embodiments, the seed layer 152 may comprise a titanium layer and a copper layer over the titanium layer. In other embodiments, the seed layer 152 comprises a copper layer in contact with the RDLs 136, the second passivation layer 140, the third passivation layer 142, and the protection layer 146. The seed layer 152 may be formed by a deposition process such as PVD, CVD, MOCVD, or the like. The seed layer 152 may be conformally deposited.

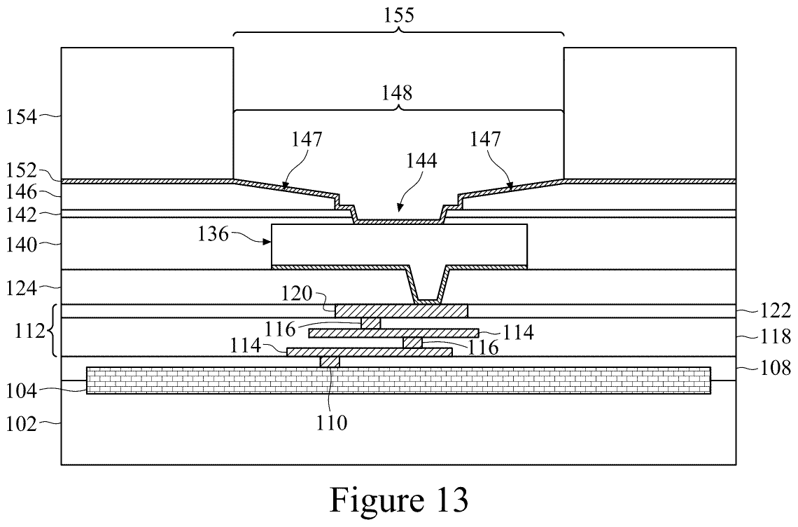

In FIG. 13, a patterned photoresist 154 is formed over the seed layer 152, in accordance with some embodiments. The patterned photoresist 154 may be formed by depositing a photosensitive layer (e.g., a photoresist or the like) over the seed layer 152 using spin coating or the like. The photosensitive layer may then be patterned by exposing the photosensitive layer to a patterned energy source (e.g., a patterned light source) and developing the photosensitive layer to remove an exposed or unexposed portion of the photosensitive layer, thereby forming an opening 155 in the patterned photoresist 154. The opening 155 exposes portions of the seed layer 152 within the recess 148. The opening 155 is aligned to the recess 148, and at least partially overlaps the recess 148. In some embodiments, the opening 155 and the recess 148 may have similar widths, and the edges of the recess 148 may be approximately aligned with the sidewalls of the opening 155. In other embodiments, the opening 155 may have a width larger than that of the recess 148 or may have a width smaller than that of the recess 148. The opening 155 in the patterned photoresist 154 corresponds to the subsequently-formed UBM 160 (described below).

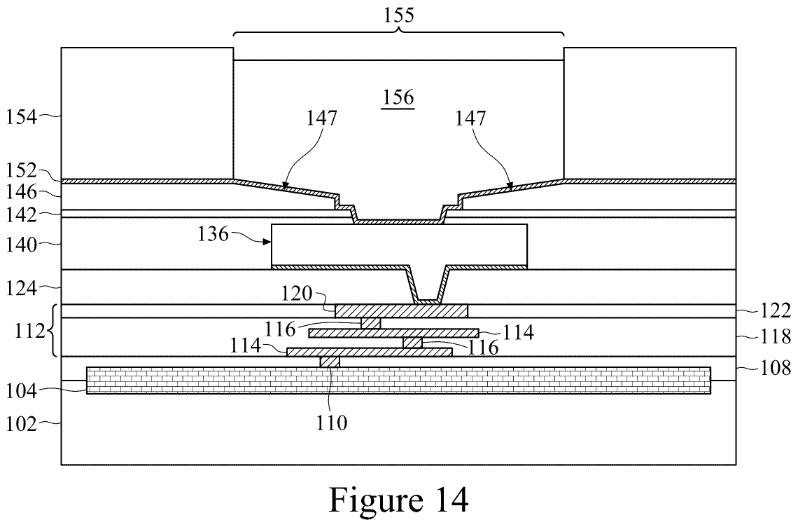

In FIG. 14, a conductive material 156 is deposited in the opening 155, in accordance with some embodiments. The conductive material 156 may be deposited using a plating process, such as electroplating, electroless plating, or the like. The conductive material 156 may comprise a metal, such as copper, nickel, silver, combinations thereof, or the like. In some embodiments, the metal(s) of the conductive material 156 may be similar to metals described previously for the conductive material 134. Other conductive materials are possible. The combination of the conductive material 156 and underlying portions of the seed layer 152 form a UBM 160 (see FIG. 15).

In FIG. 14, the patterned photoresist 154 and portions of the seed layer 152 on which the conductive material 156 is not formed are removed, in accordance with some embodiments. The patterned photoresist 154 may be removed by an acceptable ashing or stripping process, such as using an oxygen plasma or the like. Once the patterned photoresist 154 is removed, exposed portions of the seed layer 152 are removed using an acceptable etching process, such as a wet or dry etching process. The conductive material 156 and underlying remaining portions of the seed layer 152 form the UBM 160. The UBM 160 may include bump portions extending over recessed surfaces 147 of the protection layer 146. The UBM 160 may also include via portions in the first opening 144 and extending through the second passivation layer 140, the third passivation layer 142, and/or the protection layer 146 that are physically and electrically coupled to the RDL 136. As a result, the UBMs 160 are electrically coupled to devices (e.g., integrated circuit devices 104). In some embodiments, a first bottom surface of the bump portion of a UBM 160 that is near the via portion of the UBM 160 may be closer to the semiconductor substrate 102 than a second bottom surface of the bump portion of the UBM 160 that is farther from the via portion of the UBM 160.

In some embodiments, the UBM 160 fully covers the recessed surfaces 147 of the protection layer 146. For example, the sidewalls of the UBM 160 may be aligned to (e.g., vertically over) the edges of the recessed surfaces 147. In other embodiments, the sidewalls of the UBM 160 may be laterally offset from the edges of the recessed surfaces 147. For example, the sidewalls of the UBM 160 may protrude beyond the edges of the recessed surfaces 147, such as over level surfaces of the protection layer 146. In other embodiments, the UBM 160 may not completely cover the recessed surfaces 147, such that portions of the recessed surfaces 147 may be exposed.

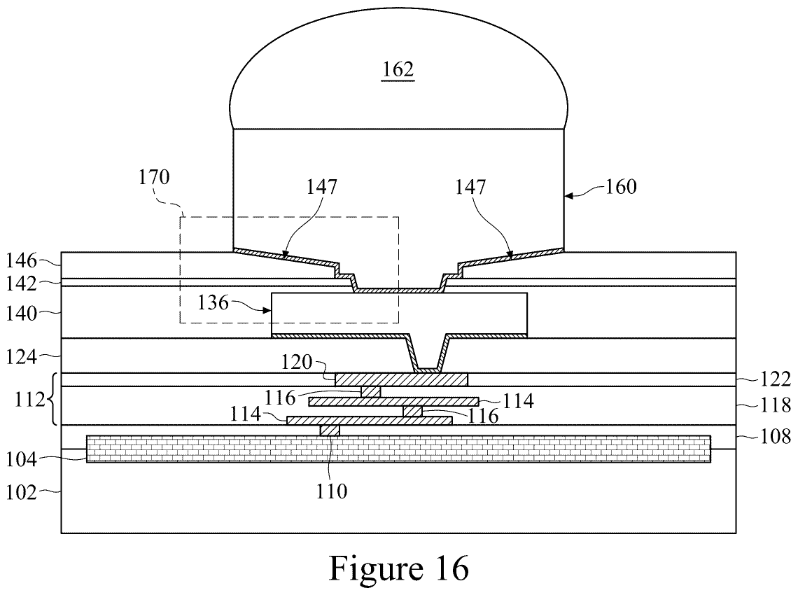

In FIG. 16, conductive connectors 162 are formed on the UBMs 160, in accordance with some embodiments. The conductive connectors 162 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 162 may include a conductive material such as solder, copper, aluminum, gold, nickel, silver, palladium, tin, the like, or a combination thereof. In some embodiments, the conductive connectors 162 are formed by initially forming a layer of solder through evaporation, electroplating, printing, solder transfer, ball placement, or the like. Once a layer of solder has been formed on the structure, a reflow may be performed in order to shape the material into the desired bump shapes. In other embodiments, the conductive material of the conductive connectors 162 is deposited on the UBMs 160 before the patterned photoresist 154 is removed.

FIGS. 17A-17F illustrate example recessed surfaces 147A-F of the protection layer 146 having different surface profiles, in accordance with some embodiments. FIGS. 17A-17F illustrate magnified cross-sectional views of a structure similar to the region 170 indicated in FIG. 16. For clarity, the seed layer 152 of the UBM 160 is not shown in FIGS. 17A-17F. The recessed surfaces 147A-F described for FIGS. 17A-17F are intended as non-limiting examples, and other profiles, dimensions, shapes, configurations, or arrangements are possible. The recessed surfaces 147A-F may be formed using techniques similar to those described for FIGS. 10-11 for forming recessed surfaces 147. For example, the recessed surfaces 147A-F may be formed in the protection layer 146 using grayscale photolithography techniques and/or using multiple exposures. Forming a protection layer 146 with recessed surfaces 147 underneath a UBM 160 may reduce interface stress and may reduce the chance of delamination or other defects. The particular surface profile of a recessed surface 147 underneath a UBM 160 may depend on the particular arrangement or configuration of the structure.

FIG. 17A illustrates a recessed surface 147A having a sloped surface profile, in accordance with some embodiments. The recessed surface 147A of FIG. 17A may be similar to the recessed surfaces 147 of FIGS. 11-16. For example, protection layer 146 may have a recessed surface 147A underneath the UBM 160 that is sloped, such that the thickness of the protection layer 146 tapers toward the via portion of the UBM 160. For example, the protection layer 146 may taper from a thickness T1 to a smaller thickness T2 at or near the sidewall 147′ of the protection layer 146. In some embodiments, the thickness T2 is between about 10% and about 90% of the thickness T 1. In some embodiments, the thickness T2 may be in the range of about 1 μm to about 2 μm. Other thicknesses are possible. The recessed surface 147A may be substantially planar or may be contoured. The recessed surface 147A may have an angle A1 with respect to a top surface of the protection layer 146 that is in the range of about 1 degree to about 45 degrees, though other angles are possible. The sidewall 147′ of the protection layer 146 may be laterally offset from the edge (e.g., sidewall) of the second passivation structure by a distance D1 in the range of about 0 μm to about 20 μm, though other distances are possible. In some embodiments in which the distance D1 is nonzero, the recessed surface 147A may form a single “step” from the protection layer 146 to the third passivation layer 142. The sidewall 147′ may be substantially vertical, as shown in FIG. 17A, or may be sloped or curved.

FIG. 17B illustrates a recessed surface 147B having a stepped surface profile, in accordance with some embodiments. The recessed surface 147B comprises a first “step” over the second passivation structure that has a sidewall height H1 and a length L1 and a second “step” over the second passivation structure that has a sidewall height H2 and a length L2. The total height H1+H2 may be approximately the same as the thickness T1 of the protection layer 146, in some embodiments. The heights H1 and H2 may be similar or different. The total length L1+L2 may be approximately the same as the length of the recessed surface 147B underneath the UBM 160, in some embodiments. The lengths L1 and L2 may be similar or different. In some cases, a top surface of the protection layer 146 covered by the UBM 160 may be considered part of the recessed surface 147B even though it may be approximately level with a top surface of the protection layer 146 that is not covered by the UBM 160. In other cases, only the surfaces of portions of the protection layer 146 that are thinner than the thickness T1 are considered part of the recessed surface 147B. The various surfaces of the recessed surface 147B may be approximately horizontal or approximately vertical as shown in FIG. 17B, or may be sloped (e.g., oblique from horizontal or vertical).

A recessed surface 147 may have any suitable number of steps in any stepped embodiments. For example, FIG. 17C illustrates a recessed surface 147C having a stepped surface with three steps, in accordance with some embodiments. The lengths of the top surfaces of the steps of the recessed surface 147C may be similar or different, and the heights of the sidewalls of the steps of the recessed surface 147C may be similar or different. A recessed surface 147 may have more than three steps in other embodiments.

FIG. 17D illustrates a recessed surface 147D having a surface profile comprising a combination of sloped surfaces and steps, in accordance with some embodiments. The recessed surface 147D is similar to the recessed surface 147B, except that the steps of the recessed surface 147D has sloped sidewalls instead of vertical sidewalls. For example, the first (e.g., lowest) step of the recessed surface 147D has a sidewall sloping at angle A1, and the second step of the recessed surface 147D has a sidewall sloping at angle A2. The angles A1 and A2 may each be in the range of about 1°to about 90°. The top surfaces of the steps may be substantially horizontal or may be sloped, and may have similar or different lengths. The heights of the steps may be similar or different. Another number of steps may be present in other embodiments.

FIG. 17E illustrates a recessed surface 147E having a surface profile comprising a combination of sloped surfaces and steps, in accordance with some embodiments. The recessed surface 147E is similar to the recessed surface 147D, except that a top surface of the first (e.g., lowest) step of the recessed surface 147E is sloped. For example, the first step of the recessed surface 147E has a sidewall sloping at angle A1, the second step of the recessed surface 147E has a sidewall sloping at angle A2, and the top surface of the first step has an angle A3 with respect to the sidewall of the second step. In other words, the angle of the sidewall of the second step relative to the top surface of the second step is A2, the angle of the top surface of the first step relative to the sidewall of the second step is A3, and the angle of the sidewall of the first step relative to the top surface of the first step is A1. The angles A1, A2, and A3 may each be in the range of about 1°to about 90°. In some embodiments, the sum of all of the relative angles (e.g., A1+A2+A3) of the recessed surface 147E may be greater than 90°. In other words, the total rotation along a continuous path from a first edge (e.g., point P1 in FIG. 17E) of a recessed surface 147E to a second edge (e.g., point P2 in FIG. 17E) of the recessed surface 147E may be greater than 90°. In other embodiments, more than one step may have a sloped top surface. In such embodiments, the sum of the relative angles between the sidewalls and the top surfaces of the steps may sum to greater than 90°. In some cases, having the sum of all relative angles of the steps of a recessed surface 147 be greater than about 90°may reduce interface stress and reduce the risk of defects. Another number of steps or sloped surfaces may be present in other embodiments.

FIG. 17F illustrates a recessed surface 147F having a curved surface profile, in accordance with some embodiments. While the recessed surfaces 147A-E are shown having substantially straight (e.g., planar) surfaces, in other embodiments some or all of a recessed surface 147 may be curved. An example curved recessed surface 147F is shown in FIG. 17F as an illustrative example, but any suitable curved surface profile may be formed in other embodiments. In some embodiments, a recessed surface 147 may have a generally stepped shape with one or more curved portions. In some embodiments, a recessed surface 147 may comprise substantially straight surfaces separated by curved surfaces. For example, in some embodiments, the top surfaces of the steps of a recessed surface 147 may be straight (e.g., horizontal or sloped), and the sidewalls between the steps may be curved. Other surface profiles are possible.

Embodiments may achieve various advantages. Forming a protection layer (e.g., a polymer layer or the like) such that portions covered by an under bump metallization (UBM) are sloped and/or stepped can reduce interface stress. For example, interface stress between the protection layer and an underlying passivation layer or between the protection layer and an overlying UBM can be reduced. In some cases, the interface stress may be reduced by about 15% or more. Reducing stress in this manner can reduce the risk of defects such as delamination, cracking, or warping. Accordingly, yield, reliability, and performance of a package may be improved. The recessed portions of the protection layer may be formed having particular surface profiles suited to a particular application or structure. The surface profile of the protection layer may be controlled using techniques described herein, such as utilizing grayscale photolithography or multiple exposure photolithography.

In some embodiments, a method includes forming a passivation structure over a first conductive feature; forming an opening in the passivation structure to expose the first conductive feature; forming a protection layer over the passivation structure and within the opening, wherein the protection layer over the passivation structure has a first thickness; recessing a portion of the protection layer to form a recess, wherein the recess exposes the first conductive feature, wherein a second thickness of the protection layer at a sidewall of the recess is smaller than the first thickness; and forming a second conductive feature over the protection layer and within the recess. In an embodiment, a top surface of the recessed portion of the protection layer is sloped. In an embodiment, the sloped top surface extends from an edge of the second conductive feature over the protection layer to the sidewall of the recess. In an embodiment, the recess exposes a top surface of the passivation structure. In an embodiment, the passivation structure includes a layer of silicon nitride over a layer of silicon oxide. In an embodiment, a width of the recess is larger than a width of the first conductive feature. In an embodiment, recessing the portion of the protection layer includes performing a grayscale photolithography process. In an embodiment, the protection layer includes polyimide. In an embodiment, a top surface of the recessed portion of the protection layer has a stepped profile.

In some embodiments, a method includes forming a first passivation layer over a redistribution line; patterning the first passivation layer to form a first opening that exposes a first surface the redistribution line; depositing a polymer layer over the first passivation layer and the first surface of the redistribution line; patterning the polymer layer to form a second opening that exposes the first surface of the redistribution line, wherein the patterning reshapes a top surface of the polymer layer adjacent the second opening; and forming an under bump metallization (UBM) that covers the first surface of the redistribution line and the reshaped top surface of the polymer layer. In an embodiment, the reshaped top surface of the polymer layer surrounds the second opening. In an embodiment, the reshaped top surface of the polymer layer includes multiple stepped surfaces. In an embodiment, at least one of the stepped surfaces is sloped. In an embodiment, at least two of the stepped surfaces have different lengths. In an embodiment, a sidewall of the polymer layer at the second opening has a first height, wherein the polymer layer adjacent the UBM has a first thickness, wherein the first height is smaller than the first thickness.

In some embodiments, a package includes a dielectric layer over a conductive feature; a polymer layer over the dielectric layer, wherein the polymer layer includes a stepped upper surface; and an under bump metallization (UBM) over the stepped upper surface of the polymer layer, wherein the UBM extends through the polymer layer and the dielectric layer to contact the conductive feature. In an embodiment, the stepped upper surface includes multiple horizontal surfaces separated by sloped surfaces. In an embodiment, the stepped upper surface includes multiple horizontal surfaces separated by curved surfaces. In an embodiment, the stepped upper surface laterally surrounds the conductive feature. In an embodiment, the stepped upper surface includes a sloped top surface.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a passivation structure over a first conductive feature;
forming an opening in the passivation structure to expose the first conductive feature;
forming a protection layer over the passivation structure and within the opening, wherein the protection layer over the passivation structure has a first thickness;
recessing a portion of the protection layer to form a recess, wherein the recess exposes the first conductive feature, wherein a second thickness of the protection layer at a sidewall of the recess is smaller than the first thickness; and
forming a second conductive feature over the protection layer and within the recess.

2. The method of claim 1, wherein a top surface of the recessed portion of the protection layer is sloped.

3. The method of claim 2, wherein the sloped top surface extends from an edge of the second conductive feature over the protection layer to the sidewall of the recess.

4. The method of claim 1, wherein the recess exposes a top surface of the passivation structure.

5. The method of claim 1, wherein the passivation structure comprises a layer of silicon nitride over a layer of silicon oxide.

6. The method of claim 1, wherein a width of the recess is larger than a width of the first conductive feature.

7. The method of claim 1, wherein recessing the portion of the protection layer comprises performing a grayscale photolithography process.

8. The method of claim 1, wherein the protection layer comprises polyimide.

9. The method of claim 1, wherein a top surface of the recessed portion of the protection layer has a stepped profile.

10. A method comprising:
forming a first passivation layer over a redistribution line;
patterning the first passivation layer to form a first opening that exposes a first surface the redistribution line;
depositing a polymer layer over the first passivation layer and the first surface of the redistribution line;
patterning the polymer layer to form a second opening that exposes the first surface of the redistribution line, wherein the patterning reshapes a top surface of the polymer layer adjacent the second opening; and
forming an under bump metallization (UBM) that covers the first surface of the redistribution line and the reshaped top surface of the polymer layer.

11. The method of claim 10, wherein the reshaped top surface of the polymer layer surrounds the second opening.

12. The method of claim 10, wherein the reshaped top surface of the polymer layer comprises a plurality of stepped surfaces.

13. The method of claim 10, wherein at least one of the stepped surfaces is sloped.

14. The method of claim 10, wherein at least two of the stepped surfaces have different lengths.

15. The method of claim 10, wherein a sidewall of the polymer layer at the second opening has a first height, wherein the polymer layer adjacent the UBM has a first thickness, wherein the first height is smaller than the first thickness.

16. A package comprising:
a dielectric layer over a conductive feature;
a polymer layer over the dielectric layer, wherein the polymer layer comprises a stepped upper surface; and
an under bump metallization (UBM) over the stepped upper surface of the polymer layer, wherein the UBM extends through the polymer layer and the dielectric layer to contact the conductive feature.

17. The package of claim 16, wherein the stepped upper surface comprises a plurality of horizontal surfaces separated by sloped surfaces.

18. The package of claim 16, wherein the stepped upper surface comprises a plurality of horizontal surfaces separated by curved surfaces.

19. The package of claim 16, wherein the stepped upper surface laterally surrounds the conductive feature.

20. The package of claim 16, wherein the stepped upper surface comprises a sloped top surface.
